(19) United States
(12) Patent Application Publication
(10) Pub. No.: US 2008/0237764 A1
(43) Pub. Date: Oct. 2, 2008

(54) SEMICONDUCTOR ELEMENT AND METHOD FOR MANUFACTURING THE SAME

(75) Inventor: Tomoyuki Kikuchi, Minami-Ashigara-shi (JP)

Correspondence Address: BIRCH STEWART KOLASCH & BIRCH, PO BOX 747, FALLS CHURCH, VA, 22040-0747, US

(73) Assignee: FUJIFILM Corporation, Tokyo (JP)

(21) Appl. No.: 12/058,422

(22) Filed: Mar. 28, 2008

(30) Foreign Application Priority Data
Mar. 30, 2007 (JP) 2007-095558

(51) Int. Cl. H01L 31/0232; H01L 31/18

(52) U.S. Cl. 257/432; 438/70; 257/E31.127

(57) ABSTRACT

A semiconductor element comprises: a semiconductor substrate; and an amorphous metal oxide film as a first film deposited on the semiconductor substrate. By providing the amorphous metal oxide film as the first film, a recess with a large aspect ratio can be filled. As a result, a void/crack-free film of excellent quality can be formed.

### BACKGROUND OF THE INVENTION

1. Field of the Invention

The present invention relates to a semiconductor element and a method for manufacturing the same, and particularly to a semiconductor element including an amorphous metal oxide and a method for manufacturing such a semiconductor element.

2. Description of the Related Art

In a conventional solid-state imaging element, such as a CCD (Charge Coupled Device), each pixel has an area that does not contribute to photoelectric conversion, such as a transfer register, so that the aperture ratio of the light-receiving plane of the light-receiving section to the entire pixel plane is low. The aperture ratio should be increased to improve sensitivity of the light-receiving section. To this end, a solid-state imaging element has been proposed in which a top tens is formed on the surface of a color filter and an in-layer lens, a waveguide and the like are formed between the light-receiving section and the color filter for effective use of incident light.

Japanese Patent Application Laid-Open No. 9-64325 discloses formation of an SiN film as an in-layer lens by using atmospheric pressure CVD (Chemical Vapor Deposition) or plasma CVD.

Japanese Patent Application Laid-Open No. 2003-298034 discloses formation of a waveguide by filling an organic polymer with a high refractive index.

Japanese Patent Application Laid-Open No. 2004-221487 discloses formation of an in-layer lens on a BPSG film by forming a photosensitive material film a containing a metal oxide and having a refractive index higher than that of the BPSG film, and exposing the material film to light, followed by development.

Japanese Patent Application Laid-Open No. 2006-156799 discloses formation of an in-layer lens made of a highly refractive resist material having metal oxide particles dispersed therein.

In recent years, reduction in size and increase in the number of pixels of a solid-state imaging device reduce the area of the light-receiving section per unit pixel and increase the aspect ratio (ratio of the width to the depth) of the underlying stepped portion in which an in-layer lens is formed. Therefore, in the method for forming the in-layer lens disclosed in Japanese Patent Application Laid-Open No. 9-64325 by using an atmospheric pressure CVD or plasma CVD apparatus, the increase in aspect ratio degrades the coverage indicative of how well the underlying stepped portion is filled, so that voids and the like are produced. Voids blocks incident light from being collected at the light-receiving section, and hence reduce light-receiving sensitivity, which is one of fundamental performance indicators of a solid-state imaging device, resulting in poor image quality.

The in-layer lens is typically formed of an SiN film having a refractive index (approximately 2.0) higher than that of a transparent film by using CVD. However, in the in-layer lens formed by filling an organic polymer as described in Japanese Patent Application Laid-Open No. 2003-298034, no organic polymer can provide a high refractive index of at least 1.71.

In the in-layer lens formed by filling an organic polymer containing a metal oxide and having a refractive index higher than that of the transparent film as described in Japanese Patent Application Laid-Open No. 2004-221487 and No. 2006-156799, introduction of a high-temperature process as a post process, such as plasma CVD, produces cracks and separation of the film due to a film shrinkage-induced stress and hence causes defects in the shape of the in-layer lens, resulting in degraded image quality. Further, use of a photosensitive material requires light exposure and development steps, so that the number of steps increases.

### SUMMARY OF THE INVENTION

The present invention has been made to solve the above problems and provides a semiconductor element having an in-layer lens being convex toward a light-receiving surface of a solid-state imaging element, the in-layer lens which has an excellent film quality free from voids and cracks, and thus has a light-collecting function even when the aspect ratio of upper side of the light-receiving surface increases with the increase of the number of pixels, as well as a method for manufacturing such a semiconductor element.

To achieve the above object, the semiconductor element according to the present invention includes: a semiconductor substrate; and an amorphous metal oxide film as a first film deposited on the semiconductor substrate.

By providing the amorphous metal oxide film as the first film, a recess can be filled with the first film even when the aspect ratio of upper side of the light-receiving surface is large. As a result, a void/crack-free film of excellent quality can be formed. Further, since the metal oxide film is amorphous and hence heat resistant, a high-temperature process, such as atmospheric pressure CVD or plasma CVD, can be introduced as a post step.

In the semiconductor element according to the above aspect of the present invention, the first film may contain two or more types of metal oxides. Inclusion of two or more types of metal oxides allows easy adjustment of properties of the first film, such as the refractive index.

The semiconductor element according to the above aspect of the present invention further includes a solid-state imaging element. The solid-state imaging element includes: a light-receiving section formed in the semiconductor substrate, the light-receiving section performing photoelectric conversion; a light blocking film having an opening formed above the light-receiving section; a transparent film formed on the opening in the light blocking film, the transparent film having a recess; an in-layer lens formed in the recess in the transparent film, the in-layer lens formed of the first film and a second film; and a color filter and a top lens formed above the in-layer lens, wherein the first film is located in the recess in the transparent film and at a level lower than the outer side of the transparent film.

In the semiconductor element, particularly in the semiconductor element including the solid-state imaging element, by providing the amorphous metal oxide film as the first film in the recess where is a portion lower than the outer side of the transparent film, an in-layer lens formed of a void/crack-free film of excellent quality can be formed. Further, since the metal oxide film formed in the recess is amorphous, cracks due to stress will not be produced. An amorphous metal oxide film has a relatively high transmittance and is hence suitable for a solid-state imaging element.

In the semiconductor element according to the above aspect of the present invention, when a shape of the recess formed in the transparent film is described using an isosceles triangle, the isosceles triangle having a tangent line which is tangent to a portion where a tilt angle is the steepest on an outer film surface of the transparent film as one of two sides of an equal length, and having an intersection of a surface of the recess and a center line of the opening as an apex, an angle of the apex of the isosceles triangle is smaller than 180 degrees, preferably at least 20 degrees but smaller than or equal to 140 degrees. By configuring the shape of the recess in consideration of the above angle range, the first film can be reliably filled in the recess.

In the semiconductor element according to the above aspect of the present invention, the pixel pitch of the solid-state imaging element is 3.0 μm or smaller, preferably 2.0 μm or smaller, more preferably 1.0 μm or smaller. In particular, even in a solid-state imaging element in which the pixel pitch is small and the aspect ratio of the recess is large, an in-layer lens formed of a void/crack-free film of excellent quality can be formed.

In the semiconductor element according to the above aspect of the present invention, the metal oxide is produced from a precursor polymer. An amorphous metal oxide film can be easily produced from a precursor polymer.

In the semiconductor element according to the above aspect of the present invention, the metal oxide is any of titanium oxide, zirconium oxide, silicon oxide, indium oxide, zinc oxide, and tantalum oxide, and the refractive index of the metal oxide in the visible spectrum is at least 1.6. Examples of preferred metal oxides are identified above.

In the semiconductor element according to the above aspect of the present invention, the first film is formed by using an application method. An application method allows easy and simple formation of the first film.

The method for manufacturing a semiconductor element according to the present invention includes the steps of: forming a light-receiving section in a semiconductor substrate, the light-receiving section performing photoelectric conversion; forming a light blocking film having an opening above the light-receiving section; forming a transparent film with a recess at the opening in the light blocking film; forming an in-layer lens in the recess in the transparent film, the in-layer lens formed of a first film and a second film; and forming a color filter and a top lens above the in-layer lens, wherein in the first film formation step, an application liquid produced by solving a precursor polymer having a solid content of 0.01% to 20% in an organic solvent is used.

By using an application liquid produced by solving the precursor polymer having a solid content of 0.01% to 20% in an organic solvent, the application liquid can reliably fill the recess.

In the method for manufacturing a semiconductor element according to the above aspect of the present invention, the first film formation step includes the steps of: dripping 2 to 6 cubic centimeters of the application liquid; forming a film by spinning the dripped application liquid at 500 to 4000 rpm; drying the film on a hot plate heated to 60 to 450° C. for 1 to 10 minutes; and baking the film in an anneal furnace heated to 200 to 750° C. for 10 to 60 minutes. Preferred conditions in the first film formation step are identified above.

In the method for manufacturing a semiconductor element according to the above aspect of the present invention, the first film formation step is a sol-gel method in which the precursor polymer goes through hydrolysis and dehydrating condensation reactions, because the sol-gel method is suitable for manufacturing an amorphous metal oxide film.

In the method for manufacturing a semiconductor element according to the above aspect of the present invention, the first film formation step includes the step of repeating the application and drying multiple times and then finally baking the first film in an anneal furnace heated to 200 to 750° C. for 10 to 60 minutes. In this way, resistance to cracking is improved and the void prevention effect is improved.

In the method for manufacturing a semiconductor element according to the above aspect of the present invention, the refractive index of the first film can be adjusted to a desired value by controlling the mixing ratio of two or more types of metal oxides. Since the refractive index of the first film formed in the light path in the solid-state imaging element can be adjusted to a desired value, functions required as a solid-state imaging element are improved.

In the method for manufacturing a semiconductor element according to the above aspect of the present invention, the in-layer lens formation step includes: a first step of forming the first film in the recess being lower than an outer side of the transparent film; and a second step of forming the second film having optical transparency by chemical vapor deposition. Preferred conditions and process in the first film formation step are identified above.

In the method for manufacturing a semiconductor element according to the above aspect of the present invention, when a film thickness of the first film is described using an isosceles triangle, the isosceles triangle having a tangent line which is tangent to a portion where a tilt angle is the steepest on an outer film surface of the transparent film and the first film as one of two sides of an equal length, and having an intersection of a surface of the first film filling the recess and a center line of the opening as an apex, an angle of the apex of the isosceles triangle is smaller than 180 degrees, preferably at least 60 degrees.

Even when the aspect ratio of the underlying stepped portion (aspect ratio of the recess) on which the in-layer lens is formed is large, the first film with the film thickness described above is formed in the recess. Therefore, the aspect ratio of the recess becomes effectively small when the second film, which is part of the in-layer lens, is formed. As a result, an in-layer lens formed of a void/crack-free film of excellent quality can be formed.

As described above, according to the semiconductor element and the method for manufacturing the same of the present invention, a semiconductor element having a light-collecting in-layer lens is provided, the in-layer lens being convex toward the light-receiving surface of the solid-state imaging element and formed of a void/crack-free film of excellent quality even when the aspect ratio defined above the light-receiving surface increases as the number of pixels increases. Further, a method for manufacturing such a semiconductor element is provided.

### BRIEF DESCRIPTION OF THE DRAWINGS

FIG. 1 is a cross-sectional view showing an embodiment of the solid-state imaging element according to the present invention;

FIG. 2 is a cross-sectional view showing the shape of a recess in the solid-state imaging element according to an embodiment;

FIG. 3 is a cross-sectional view showing the shape of a second film in the recess in the solid-state imaging element according to the embodiment;

FIGS. 4A to 4D explain the flow of a method for manufacturing the solid-state imaging element according to the embodiment; and

FIG. 5 is a graph showing the change in refractive index.

### DETAILED DESCRIPTION OF THE PREFERRED EMBODIMENTS

Preferred embodiments of the solid-state imaging element and the method for manufacturing the same according to the present invention will be described below with reference to the accompanying drawings.

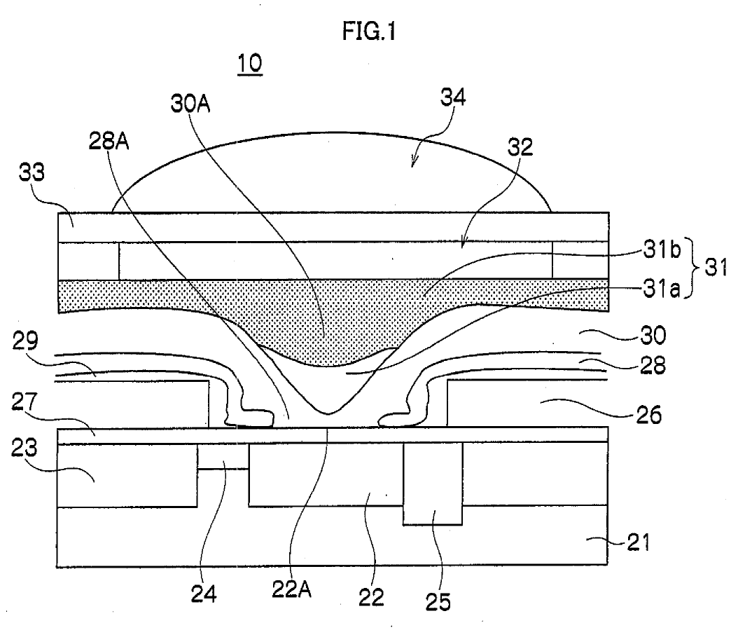

FIG. 1 is a cross-sectional view showing an embodiment of the solid-state imaging element according to the present invention. The solid-state imaging element 10 includes: a semiconductor substrate 21; a photodiode (light-receiving section) 22 which is a light-receiving element formed in the semiconductor substrate 21 and performs photoelectric conversion; a charge transfer section 23 that transfers the photoelectrically converted charge out of the photodiode 22; a readout gate 24 that carries the charge produced in the light-receiving section 22 to the charge transfer section 23; an element isolator 25 that prevents the charge from leaking; a transfer electrode 26 that transfers the photoelectrically converted charge out of the photodiode 22; an insulating film 27 formed on the surface of the semiconductor substrate 21; a light blocking film 28 that covers the transfer electrode 26 but has an opening above the light receiving section 22; an interlayer insulating film 29 provided between the light blocking film 28 and the transfer electrode 26; a transparent film 30 that covers the light blocking film 28 and the light-receiving section 22; a material film (first film) 31a formed on the transparent film 30; a material film (second film) 31b formed on the material film (first film) 31a; a color filter 32 provided on the material film 31b; a planarization layer 33; and a top lens 34 formed on the planarization layer 33. In this embodiment, an in-layer lens 30 is formed of the material film (first film) 31a and the material film (second film) 31b.

The photodiode 22, a readout section and a transfer register (not shown), the transfer electrode 26, the light blocking film 28, and the like form the portion called a CCD. The light blocking film 28 has an opening 28A at the portion corresponding to the light-receiving surface 22A of the photodiodes 22. The opening 28A is formed not to block the light incident on the light-receiving surface 22A but block the light incident on the other portions. Since the basic configuration of a CCD described so far is generally well known, detailed description thereof will be omitted.

In the solid-state imaging element according to the present invention, the transparent film 30 is formed to have a concave portion, that is, a recess 30A, above the light-receiving section 22. The transparent film 30 is typically made of SiO₂-based (silicon oxide-based) material, which is transparent and has a refractive index of approximately 1.45. Examples of the SiO₂-based material may be BPSG, plasma SiO₂, and SOG. A transparent film made of BPSG is particularly preferable, and the film thickness thereof ranges from 100 to 2000 nm, preferably 200 to 300 nm.

The recess 30A may be formed by using the concave-convex shape formed on the semiconductor substrate 21, that is, the concave-convex shape made up of the protruding transfer electrode 26, light blocking film 28 and the recessed light-receiving section 22 which are formed on the semiconductor substrate 21, or by etching the surface of the formed transparent film 30.

The in-layer lens 30 is made of a transparent, high refractive-index material by using the shape of the recess 30A in the transparent film 30 to form a portion that is convex toward the light-receiving surface 22A, as shown in FIG. 1. In the present invention, as described above, the in-layer lens 30 is formed of the material film (first film) 31a and the material film (second film) 31b.

In particular, the material film (first film) 31a is greatly characterized in that it is formed of an amorphous metal oxide film.

The method for forming an in-layer lens by using an atmospheric pressure CVD or plasma CVD apparatus is a well known method. However, increasing demand to reduce the size of a solid-state imaging element has increased the aspect ratio of the recess. When an in-layer lens is formed by using an atmospheric pressure CVD or plasma CVD apparatus, the coverage indicative of how well the underlying stepped portion is filled is degraded and hence voids and the like are produced. It is important to use a method for filling a material film, which becomes an in-layer lens, without producing voids in the recess 30A.

To simply fill the recess 30A, an organic polymer or an organic polymer containing a metal oxide can be used. However, not only can an organic polymer not provide an adequate refractive index, but also even an organic polymer containing a metal oxide causes cracks due to a film shrinkage-induced stress in a high-temperature process to be carried out after the in-layer lens has been formed.

An amorphous metal oxide film is characterized in that (1) the film is transparent, (2) the refractive index of the film is comparable to that of a nitride film formed by CVD, (3) the film can be formed even in a high aspect ratio recess, and (4) cracks will not be produced even when the film goes through a high-temperature process.

In the present invention, after the recess 30A is filled with the first film 31a formed of an amorphous metal oxide film, a depth of the recess 30A becomes shallow, so that formation of the second nitride film 31b by using CVD will not produce voids.

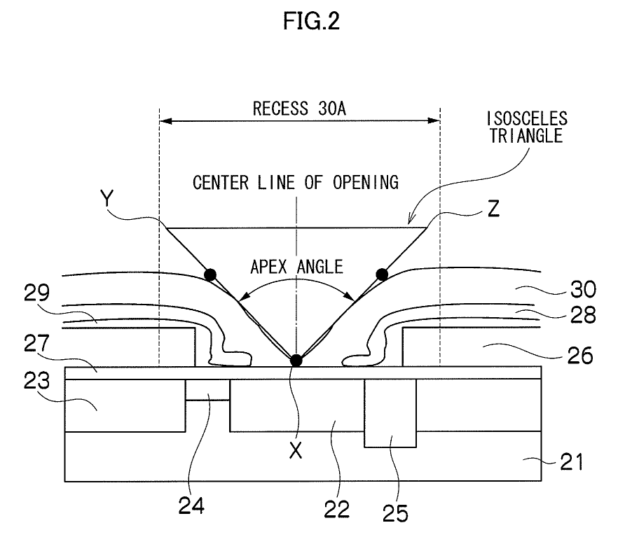

Now, consider what shape of the recess is suitable in the solid-state imaging element 10 of the present invention. In the semiconductor field, the aspect ratio (ratio of the width to the height of the opening) is critical when considering easiness of film formation. In a solid-state imaging element, since a lens convex toward the light-receiving surface is formed, the recess 30A has a substantially hemispherical shape that is slightly tapered toward the light-receiving section. In such circumstances, accurate evaluation cannot be made only by using the aspect ratio. Therefore, to evaluate the shape of the recess 30A, an apex angle X of an isosceles triangle XYZ having three points of X, Y and Z as its apexes shown in FIG. 2 is used. The isosceles triangle XYZ is set as follows.

(a) First, the portion where a tilt angle is the steepest is determined on the film surface of the recess 30A.

(b) Next, a center of an opening of the recess 30A is determined. The method to determine the center of the opening may be selected depending on the shape of the opening. For example, when the shape of the opening is substantially a circle, the center of the circle may be set as the center of the opening. When the shape of the opening is substantially an ellipse, an intersection of its major axis and its minor axis may be set as the center of the opening. When the shape of the opening is substantially a rectangle, an intersection of its diagonal lines may be set as the center of the opening.

(c) A center line of the opening which passes through the center of the opening and is perpendicular to the substrate 21 is drawn, and an intersection of the center line of the opening and the film surface of the recess 30A is set as the apex X. A tangent line is drawn from the point X to the portion where the tilt angle is the steepest on the film surface of the recess 30A, and an intersection of the tangent line and a line parallel to the substrate 21 is set as the apex Y. The tangent line is reflected along the center line of the opening (that is, the reflected line and the tangent line are symmetrical with respect to the center line of the opening), and an intersection of the reflected line and the line parallel to the substrate 21 is set as the apex Z. Finally, the isosceles triangle XYZ whose two sides of XY and XZ have an equal length is obtained.

To apply the present invention, the apex angle X of the isosceles triangle XYZ is smaller than 180 degrees, preferably at least 20 degrees but smaller than or equal to 140 degrees. When the apex angle of the recess is smaller than 140 degrees, the resin material filled in the recess exhibits an effect as in-layer lens. When the angle becomes approximately 20 degrees, it is difficult in a conventional method to prevent generation of voids in a nitride film formed by CVD. The present invention can; however accommodate a variety of shapes of the recess 30A. In particular, when the pixel pitch of the solid-state imaging element is 3.0 μm or smaller, preferably 2.0 μm or smaller, more preferably 1.0 μm or smaller, the apex angle of the shape of the recess 30A is small, and the present invention can be preferably applied.

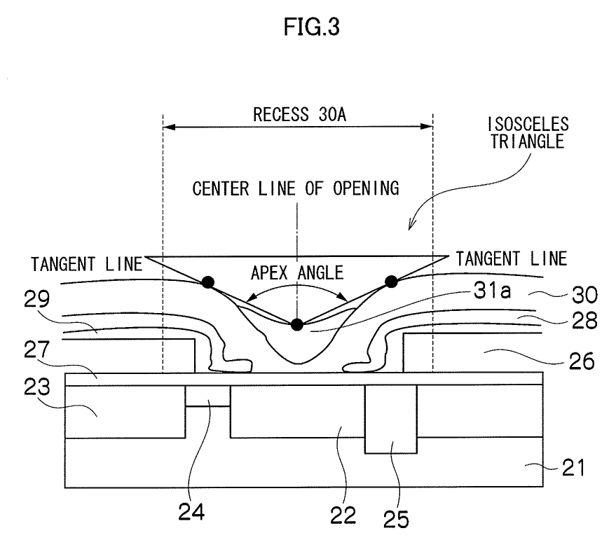

Next, consider an adequate film thickness of the first film 31a filled in the recess 30A. As described above, the recess 30A in the solid-state imaging element has a substantially hemispherical shape that is slightly tapered toward the light-receiving section. The film thickness is determined by judging whether or not voids are produced when the first film 31a and the second film 31b are sequentially formed. To study the adequate thickness of the first film 31a, an apex angle X′ of an isosceles triangle X′Y′Z′ having three points of X′, Y′ and Z′ as its apexes shown in FIG. 3 is used. The isosceles triangle X′Y′Z′ in FIG. 3 is almost set similarly to the isosceles triangle in FIG. 2; however, is different to in the following respects.

(a) In the isosceles triangle X′Y′Z′ in FIG. 3, a tangent line is drawn from the point X′ to a portion where a tilt angle is the steepest on the film surface of the transparent film 30 and the material film (the first film) 31a.

(b) The apex X′ of the isosceles triangle X′Y′Z′ in FIG. 3 is an intersection of the center line of the opening and the film surface of the material film (the first film) 31a filling the recess 30A.

That is, the position of the apex X′ of the isosceles triangle X′Y′Z′ of FIG. 3 becomes shallower than that of the apex X of the isosceles triangle XYZ of FIG. 2 by the thickness of the material film (the first film) 31a. The inventor has conducted an intensive investigation and found that the film thickness of the first film 31a may be determined in such a way that the apex angle X′ of the isosceles triangle X′Y′Z′ is smaller than 180 degrees, preferably at least 60 degrees. The reason of this is that a nitride film can be manufactured by CVD without voids when the angle is at least 60 degrees.

In the present invention, the color filter 32 is formed on the in-layer lens 30. Color filters made of an acrylic resin having red/green/blue spectral characteristics are provided above the respective photodiodes 22. To eliminate the step between the red, green, and blue filters, the planarization layer 33 is formed on the color filters 32.

The top lens 34 made of a resin is formed on the planarization layer 33. The top lens 34 is made of a material selected from the group consisting of acrylic resin, phenol resin, epoxy resin, polyester resin, urethane resin, melamine resin, urea resin, styrene resin, and silicon resin.

For example, the top lens 34 may be formed by using thermal reflow, or may be formed by using etching back. Although not illustrated, an overcoat layer may be formed for various purposes.

In the thus configured solid-state imaging element 10, the incident light is collected by the top lens 34 and the in-layer lens 30 formed of the first film 31a and the second film 31b. Since generation of voids and cracks is suppressed in the present invention, the light is efficiently collected by the light-receiving section 22.

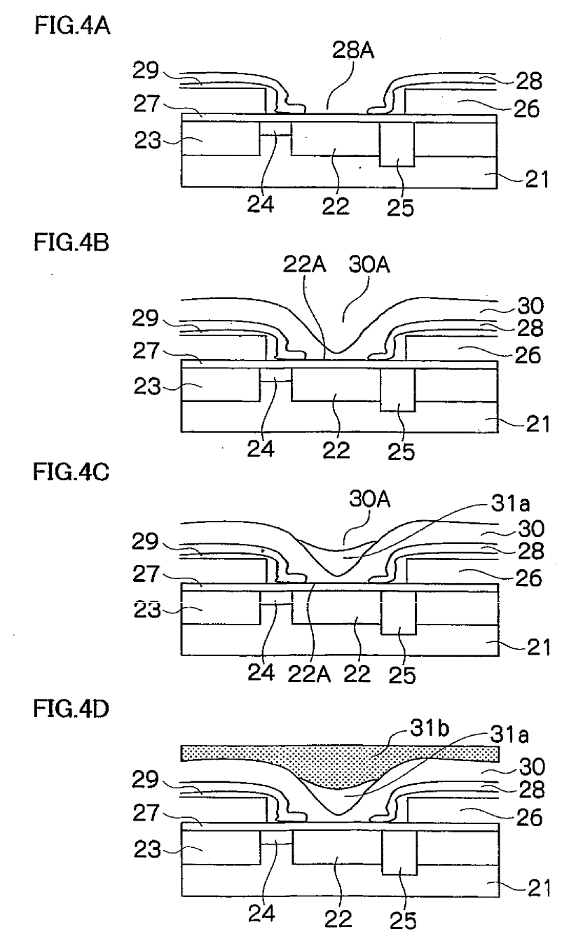

Next, a method for manufacturing the solid-state imaging element according to the first embodiment of the present invention will be described. FIGS. 4A to 4D explain the flow of a method for manufacturing the solid-state imaging element. As shown in FIG. 4A, first, a known method is used to form a CCD on the semiconductor substrate 21, the CCD including the photodiode (light-receiving section) 22, the readout section and the transfer register (not shown), the charge transfer section 23, the readout gate 24, the element isolator 25, the transfer electrode 26, the insulating film 27, the light blocking film 28, and the interlayer insulating film 29. The light blocking film 28 has the opening 28A at the position corresponding to the light-receiving section 22.

Then, as shown in FIG. 4B, the transparent film 30 that covers the photodiode 22 and the light blocking film 28 is formed. The transparent film 30 is made of a transparent material (having a refractive index of approximately 1.45). Specifically, as described above, the transparent film 30 is an SiO₂-based oxide film formed by reflowing, as required, an SiO₂ film formed by plasma CVD using TEOS as a reaction gas, or PSG, BPSG, SOG or the like formed by atmospheric pressure CVD. The cross-sectional shape of the resultant transparent film 30 has the recess 30A having a bottom and a convex portion, the shape of the bottom follows the underlying protrusion and depression structure and is convex toward the light-receiving surface 22A, the convex portion raised above the upper surface of the light blocking film 28.

Then, as shown in FIG. 4C, an amorphous metal oxide film is formed as the first film 31a on the transparent film 30, which is the underlying layer of the in-layer lens 30, so that the recess 30A is filled and a convex portion toward the light-receiving surface 22A is formed.

The film formation conditions of the first film 31a, which is an amorphous metal oxide film, which is the feature of the present invention, will now be described in detail.

### <Method for Adjusting Precursor Polymer>

The amorphous metal oxide film is produced from a precursor polymer. Specifically, the amorphous metal oxide is obtained by preparing adjusted partial hydrolysate and partial condensate of a metal alkoxide expressed by a general formula M(OR)ₙ as precursor polymers and solving them in an organic solvent.

The partial hydrolysate is obtained by hydrolyzing the metal alkoxide so that part of the hydroxyl group thereof substitutes for the alkoxide group, and expressed by a general formula M(OR)ₙ₋₁(OH). The condensate is a dimer, trimer, tetramer, or the like in which two or more molecules are condensed when the metal alkoxide is heated and dealcoholized. The hydroxyl group that has been formed facilitates condensation of the film. The partial hydrolysis can be carried out by adding water. The amount of water is 20 motes or less, preferably 0.1 to 8 motes per mole of metal alkoxide. Optimizing the amount of water prevents gelation. Since further hydrolysis and condensation makes the resultant hydrolysate and condensate insoluble in organic solvent, the adjustment is made to the extent that solubility remains. Examples of the organic solvent are hydrophilic alcohols, glycols, acetone, because water is added, combined with hydrophobic esters as appropriate. M is selected from Ti, Zn, Zr, Sn, Ta, Si, and the like.

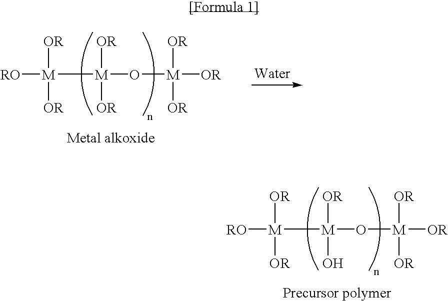

### <Method for Adjusting Application Liquid>

The precursor polymer Ti(OCH₃)ₙ₋₁(OH) having a solid content concentration of 0.1 to 20%, preferably 0.2 to 5%, is mixed with the precursor polymer Si(OCH₃)ₙ₋₁(OH) having a solid content concentration of 10% or lower, preferably 0.05 to 1%, and the mixture solved in an organic solvent is used. By changing the mixing ratio of the precursor polymer Si(OCH₃)ₙ₋₁(OH) to the precursor polymer Ti(OCH₃)ₙ₋₁(OH), the refractive index of the film and the crystallizability of TiO₂ are controlled in such a way that a desired refractive index and resistance to cracking of the film are provided. The refractive index is preferably controlled in such a way that it ranges from approximately 1.7 to 2.0, and the crystallizability is preferably controlled in such a way that an amorphous state with no anatase crystal is provided. The adjustment of the organic solvent is made to the extent that the easiness of application remains and gelation is prevented by mixing butyl acetate by 50% or higher with 1-butanol by 40% or lower. Ti and Si may be replaced with other elements, such as Zn, Zr, Sn, Ta, Mg, and Ba. Examples of the organic solvent are alcohols, such as methanol, ethanol, 1-propanol-2-propanol, 1-butanol, and 2-butanol; esters, such as ethyl acetate and butyl acetate; ethers, such as ethylene glycol and dihexyl ether; and ketones, such as acetone and methyl ethyl ketone, any of which may be used alone or the mixture of two or more solvents may be used.

<Method for Manufacturing First Film 31a>

### [Method Used in Application Step]

The application method is not limited to a specific one but may be a typical application method, such as dipping and spin coating. When film thickness uniformity is required, spin coating is preferred.

When spin coating is used, the following conditions are preferably employed. When a spin coater (SCWC80A manufactured by DAINIPPON SCREEN MFG. CO., LTD.) is used, a filter having a pore diameter of 0.1 to 0.6 μm, preferably 0.2 to 0.4 μm, is attached to the tip of the syringe, and 1 to 6 cubic centimeters, preferably 2 to 5 cubic centimeters, of the application liquid is dripped at the center of the wafer or therearound. Upon the dripping, the wafer is rotated at 100 to 1000 rpm, preferably 400 to 600 rpm, for 3 to 10 seconds, preferably 4 to 6 seconds, for spin coating. In this process, the wafer may be rotated during the dripping. Then, the wafer is rotated at 1000 to 5000 rpm, preferably 2000 to 3000 rpm, for 5 to 30 seconds, preferably 10 to 20 seconds, followed by drying.

The first film 31a is formed at a level lower than the outer side of the transparent film 30 as shown in FIG. 4C by using a low-concentration application liquid, that is, a solid content concentration of 10% or lower, preferably 0.2 to 5%. All the outer portions dry out and hence no film is formed. That is, the first film 31a is only formed in the recess 30A.

When an application liquid having a solid content concentration of 10% or higher is used, the first film 31a is also formed on the outer side portions of the transparent film 30. Further, at the positions lower than the outer side of the transparent film 30, stresses will be distributed directions other than the direction in which the film is thick, sometimes resulting in film cracking. To avoid such a situation, it is necessary to use a low-concentration application liquid to release the stresses in the direction in which the film is thick.

### [Method Used in Drying Step]

Upon the spin coating, the wafer is transferred to a semiconductor hot plate, for example, manufactured by KUROSAKI HARIMA CORPORATION, heated to 60 to 500° C., preferably 100 to 450° C., and dried for 1 to 10 minutes, preferably 1 to 4 minutes, to dry off organic substances and water.

### [Method for Applying Application Liquid Multiple Times]

By repeating the application and drying steps multiple times, the resistance to cracking is improved and a void prevention effect is provided. Therefore, the application and drying steps are preferably repeated 2 to 10 times, preferably 3 to 5 times.

### [Method Used in Baking Step]

The wafer is baked in an anneal furnace, such as a muffle furnace, Model FP410 manufactured by YAMATO SCIENTIFIC, CO., LTD, heated to 200 to 800° C., preferably 400 to 750° C., for 1 to 120 minutes, preferably 10 to 60 minutes, to form the material film (first film) 31a at a position lower than the outer side of the transparent film 30.

### [Composition and Refractive Index of First Film 31a]

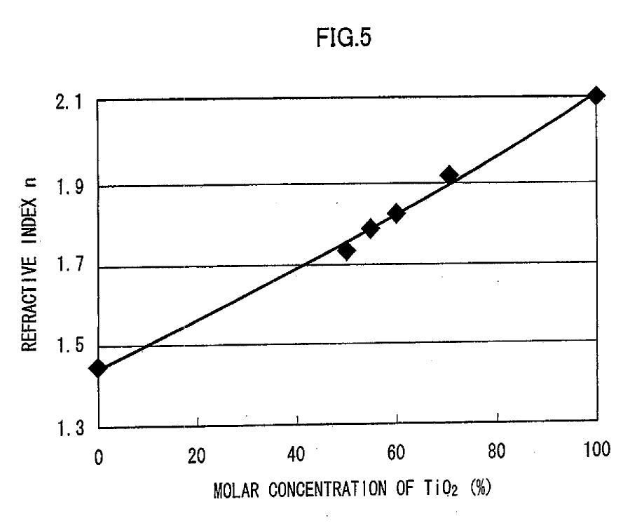

The first film 31a is made of two compounds, TiO₂ and SiO₂. The content of TiO₂ is 10% or higher, preferably 50 to 80%, and the content of SiO₂ is 90% or lower, preferably 20 to 50%. FIG. 5 is a diagram showing the relation between the molar concentration of TiO₂ and the refractive index of the resultant first film. As shown in FIG. 5, the higher the molar concentration of TiO₂ is, the higher the refractive index of the first film becomes. Therefore, by adjusting the molar ratio of TiO₂ to SiO₂ in the first film 31a, a desired refractive index is provided. When the molar concentration of TiO₂ is 50 to 80% and the molar concentration of SiO₂ is 20 to 50%, the refractive index is adjusted to 1.7 to 1.9, as shown in FIG. 5.

### [Crystallizability of First Film 31a]

The crystallizability of the TiO₂ is suppressed and hence the amorphous first film 31a is formed by combining two or more types of metal oxides, preferably combining TiO₂ with SiO₂, ZnO, ZrO, and the like. The crystallinity of the combined first film 31a is 20% or lower, preferably 3 to 15%.

Then, as shown in FIG. 4D, a single-wafer plasma CVD apparatus is used as the first step to form an SiN film having a refractive index ranging from approximately 1.9 to 2.0 on the first film 31a. The second film 31b is thus formed.

The SiN film as the second film 31b is formed to a film thickness of 200 to 700 nm, preferably 400 to 500 nm. The single-wafer plasma CVD apparatus is operated at a pressure of 399 to 798 Pa, preferably 532 to 665 Pa, an RF power of 400 to 1000 W, preferably 500 to 600 W, an RF frequency of 13.56 MHz, an electro-to-electrode distance of 10 to 15.3 mm, preferably 11.4 to 12.7 mm, a susceptor temperature of 300 to 400° C., preferably 350 to 400° C., and a flow rate of 60 to 200 sccm, preferably 120 to 150 sccm for a gas type of SiH₄, 150 to 300 sccm, preferably 180 to 250 sccm for a gas type of NH₃, and 3000 to 6000 sccm, preferably 4000 to 5000 sccm for a gas type of N₂.

After the second film 31b formed of the SiN film has been formed, a resist film (not shown) is formed on the second film 31b. The formation of the resist film is carried out by using a spin coater to apply an acrylic negative resist, followed by drying. After the drying process, the entire resist film is exposed to light in an i-line stepper, developed and post-baked.

After the resist film has been formed, an RIE (Reactive Ion Etching) apparatus is used to etch back the resist film, so that the second film 31b is planarized. The planarization may alternatively be carried out by CMP (Chemical Mechanical Polishing). Upon the planarization, the in-layer lens 31 formed of the first film 31a and the second film 31b is completed.

As described above, according to the semiconductor element and the method for manufacturing the same of the present invention, a semiconductor element having an in-layer lens being convex toward a light-receiving surface of a solid-state imaging element, the in-layer lens which has an excellent film quality free from voids and cracks, and thus has a light-collecting function even when the aspect ratio of upper side of the light-receiving surface increases with the increase of the number of pixels. Further, a method for manufacturing such a semiconductor element is provided.

What is claimed is:

1. A semiconductor element comprising:
a semiconductor substrate; and
an amorphous metal oxide film as a first film deposited on the semiconductor substrate.

2. The semiconductor element according to claim 1,
wherein the first film contains two or more types of metal oxides.

3. The semiconductor element according to claim 1, further comprising
a solid-state imaging element including:
a light-receiving section formed in the semiconductor substrate, the light-receiving section performing photoelectric conversion;
a light blocking film having an opening formed above the light-receiving section;
a transparent film formed on the opening in the light blocking film, the transparent film having a recess;
an in-layer lens formed in the recess in the transparent film, the in-layer lens formed of the first film and a second film; and
a color filter and a top lens formed above the in-layer lens,
wherein the first film is located in the recess in the transparent film and at a level lower than the outer side of the transparent film.

4. The semiconductor element according to claim 3,
wherein when a shape of the recess formed in the transparent film is described using an isosceles triangle, the isosceles triangle having a tangent line which is tangent to a portion where a tilt angle is the steepest on an outer film surface of the transparent film as one of two sides of an equal length, and having an intersection of a surface of the recess and a center line of the opening as an apex, an angle of the apex of the isosceles triangle is smaller than 180 degrees, preferably at least 20 degrees but smaller than or equal to 140 degrees.

5. The semiconductor element according to claim 3,
wherein the pixel pitch of the solid-state imaging element is 3.0 μm or smaller, preferably 2.0 μm or smaller, more preferably 1.0 μm or smaller.

6. The semiconductor element according to claim 1,
wherein the metal oxide is produced from a precursor polymer.

7. The semiconductor element according to claim 1,
wherein the metal oxide is any of titanium oxide, zirconium oxide, silicon oxide, indium oxide, zinc oxide, and tantalum oxide, and the refractive index of the metal oxide in the visible spectrum is at least 1.6.

8. The semiconductor element according to claim 1,
wherein the first film is formed by using an application method.

9. A method for manufacturing a semiconductor element comprising the steps of:
forming a light-receiving section in a semiconductor substrate, the light-receiving section performing photoelectric conversion;
forming a light blocking film having an opening above the light-receiving section;
forming a transparent film with a recess at the opening in the light blocking film;
forming an in-layer lens in the recess in the transparent film, the in-layer lens formed of a first film and a second film; and
forming a color filter and a top lens above the in-layer lens,
wherein in the first film formation step, an application liquid produced by solving a precursor polymer having a solid content of 0.01% to 20% in an organic solvent is used.

10. The method for manufacturing a semiconductor element according to claim 9,
wherein the first film formation step includes the steps of:
dripping 2 to 6 cubic centimeters of the application liquid;
forming a film by spinning the dripped application liquid at 500 to 4000 rpm;
drying the film on a hot plate heated to 60 to 450° C. for 1 to 10 minutes; and
baking the film in an anneal furnace heated to 200 to 750° C. for 10 to 60 minutes.

11. The method for manufacturing a semiconductor element according to claim 9,
wherein the first film formation step is a sol-gel method in which the precursor polymer goes through hydrolysis and dehydrating condensation reactions.

12. The method for manufacturing a semiconductor element according to claim 9,
wherein the first film formation step includes the step of
repeating the application and drying multiple times and then finally baking the first film in an anneal furnace heated to 200 to 750° C. for 10 to 60 minutes.

13. The method for manufacturing a semiconductor element according to claim 9,
wherein a refractive index of the first film can be adjusted to a desired value by controlling a mixing ratio of two or more types of metal oxides.

14. The method for manufacturing a semiconductor element according to claim 9,
wherein the in-layer lens formation step includes:
a first step of forming the first film in the recess being lower than an outer side of the transparent film; and
a second step of forming the second film having optical transparency by chemical vapor deposition.

15. The method for manufacturing a semiconductor element according to claim 9,
wherein when a film thickness of the first film is described using an isosceles triangle, the isosceles triangle having a tangent line which is tangent to a portion where a tilt angle is the steepest on an outer film surface of the transparent film and the first film as one of two sides of an equal length, and having an intersection of a surface of the first film filling the recess and a center line of the opening as an apex, an angle of the apex of the isosceles triangle is smaller than 180 degrees, preferably at least 60 degrees.
